(19) United States
(12) Patent Application Publication
(10) Pub. No.: US 2024/0321828 A1
(43) Pub. Date: Sep. 26, 2024

(54) INTEGRATED CIRCUIT STRUCTURE AND CHIP

(71) Applicant: ALi Corporation, Hsinchu City (TW)

(72) Inventors: Liang-Cai Zeng, Zhuhai (CN); YUN-JU HSIEH, Hsinchu City (TW)

(21) Appl. No.: 18/500,076

(22) Filed: Nov. 1, 2023

(30) Foreign Application Priority Data
Mar. 22, 2023 (CN) 202310286103.8

(51) Int. Cl. H01L 25/065; H01L 23/00

(52) U.S. Cl. CPC H01L 25/0657; H01L 24/48; H01L 25/0655; H01L 2224/4814; H01L 2224/48149; H01L 2224/48229; H01L 2225/06506; H01L 2225/0651; H01L 2225/06562; H01L 2924/14361

(57) ABSTRACT

An integrated circuit structure and a chip are provided. The chip includes a first pad set, a second pad set, a connection circuit, and a signal pad set. The first pad set includes a plurality of first pads. The second pad set includes a plurality of second pads respectively corresponding in position to the first pads. Each of the first pads and the corresponding second pad are electrically coupled to each other through the connection circuit so as to be operable by choosing one therefrom. The signal pad set arranged between the first pad set and the second pad set and includes a plurality of signal pads.

### CROSS-REFERENCE TO RELATED PATENT APPLICATION

This application claims the benefit of priority to Patent Application No. 202310286103.8, filed on Mar. 22, 2023 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip, and more particularly to an integrated circuit structure and a chip each having a high flexibility in use.

### BACKGROUND OF THE DISCLOSURE

Chips in a conventional integrated circuit structure can be divided into (or classified as) a stacking die or a side-by-side die according to an interior configuration thereof, such that an assembling manner of the chip is limited and inflexible. Accordingly, the conventional integrated circuit structure or the chip assembled therein is not suitable for being adjusted according to different requirements.

### SUMMARY OF THE DISCLOSURE

In response to the above-referenced technical inadequacies, the present disclosure provides an integrated circuit and a chip to effectively improve on the issues associated with conventional chips.

In order to solve the above-mentioned problems, one of the technical aspects adopted by the present disclosure is to provide an integrated circuit structure, which includes a substrate, an electronic component, and a chip. The substrate has an upper surface and a lower surface opposite to the first surface. The electronic component is disposed on the upper surface, and the electronic component is electrically coupled to the substrate in a wire-bonding manner. The chip comprises a connection circuit, a first pad set, a signal pad set, and a second pad set. The first pad set, the signal pad set, and the second pad set are sequentially arranged on a top surface of the chip along a layout direction. The first pad set and the second pad set are electrically coupled to each other through the connection circuit, so that the chip is selectively operable in a stacking mode through the first pad set or a side-by-side mode through the second pad set. When the chip is operated in the stacking mode, the chip is stacked onto the electronic component, the signal pad set is electrically coupled to the electronic component in a wire-bonding manner, and the first pad set is electrically coupled to the substrate in a wire-bonding manner. When the chip is operated in the side-by-side mode, the chip is disposed on the upper surface of the substrate, the signal pad set is electrically coupled to the electronic component, and the second pad set is electrically coupled to the substrate in a wire-bonding manner.

In order to solve the above-mentioned problems, another one of the technical aspects adopted by the present disclosure is to provide a chip, which includes a first pad set, a second pad set, a connection circuit, and a signal pad set. The first pad set includes a plurality of first pads. The second pad set includes a plurality of second pads respectively corresponding in position to the first pads. Each of the first pads and the corresponding second pad are electrically coupled to each other through the connection circuit so as to be operable by choosing one therefrom. The signal pad set is arranged between the first pad set and the second pad set and includes a plurality of signal pads.

In order to solve the above-mentioned problems, yet another one of the technical aspects adopted by the present disclosure is to provide a chip, which includes a main portion, a pad set, a signal pad, and a connection circuit. The main portion includes a top surface and a circuit assembly that is arranged under the top surface. The pad set includes a first pad and a second pad both being arranged on the top surface. The signal pad is arranged on the top surface of the main portion and is electrically coupled to the circuit assembly. The first pad, the signal pad, and the second pad are arranged sequentially in a predetermined order along a layout direction defined toward a periphery of the chip. The connection circuit is arranged under the top surface. The connection circuit includes a first segment electrically coupled to the first pad, a second segment electrically coupled to the second pad, and a common segment that is electrically coupled to the circuit assembly. When the circuit assembly is electrically coupled to an object outside of the chip through the pad set, the pad set is operable by choosing one of the first pad and the second pad to be electrically coupled to the object in a wire-bonding manner.

Therefore, in any one of the integrated circuit structure and the chip provided by the present disclosure, the first pad set (e.g., the first pad) and the second pad set (e.g., the second pad) are cooperated with the connection circuit for being electrically coupled to each other, so that the chip can have a high flexibility in use. For example, the chip can be operated by choosing one of the first pad set (e.g., the first pad) and the second pad set (e.g., the second pad), thereby enabling the chip to be assembled in the stacking mode or in the side-by-side mode according to different requirements.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of an integrated circuit structure in a stacking mode according to a first embodiment of the present disclosure;

FIG. 2 is a schematic top view of FIG. 1;

FIG. 3 is a schematic side view of the integrated circuit structure in a side-by-side mode according to the first embodiment of the present disclosure;

FIG. 4 is a schematic top view of FIG. 3;

FIG. 5 is a schematic side view of the integrated circuit structure having another configuration in the side-by-side mode according to the first embodiment of the present disclosure;

FIG. 6 is a schematic top view of FIG. 5;

FIG. 7 is a schematic side view of a chip according to a second embodiment of the present disclosure;

FIG. 8 is a schematic top view of FIG. 7;

FIG. 9 is a schematic top view of the integrated circuit structure in the side-by-side mode according to a third embodiment of the present disclosure; and

FIG. 10 is a schematic top view of the integrated circuit structure having another configuration in the side-by-side mode according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

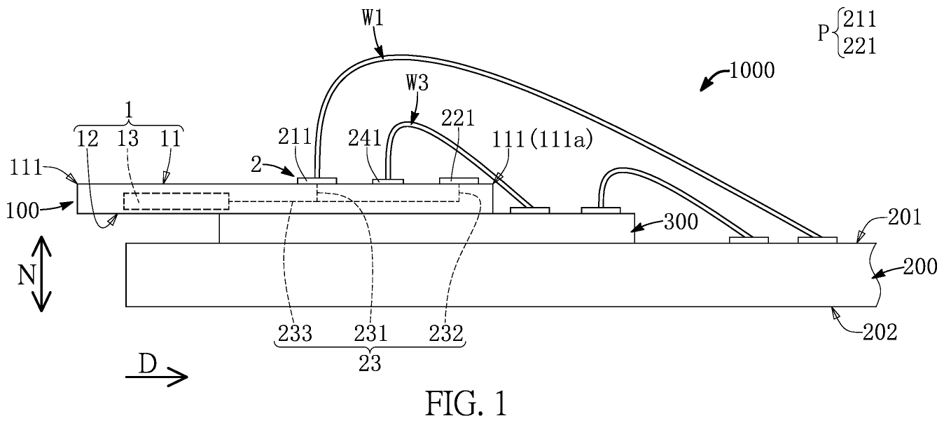

Referring to FIG. 1 to FIG. 6, a first embodiment of the present disclosure is provided. The present embodiment provides an integrated circuit structure 1000, which includes a substrate 200, an electronic component 300 disposed on the substrate 200, and a chip 100 that is capable of being selectively disposed on the substrate 200 or the electronic component 300, but the present disclosure is not limited thereto. For example, in other embodiments of the present disclosure not shown in the drawings, the chip 100 can be independently used (e.g., sold) or can be used in cooperation with other components. It should be noted that, in order to clearly describe the present embodiment, the following description describes the structure and connection relationship of each component of the chip 100.

The chip 100 includes a main portion 1 and an external connection portion 2 that is formed on the main portion 1. The main portion 1 has a top surface 11, a bottom surface 12 being opposite to the top surface 11, and a circuit assembly 13 that is arranged under the top surface 11. It should be noted that the circuit assembly 13 in the present embodiment is embedded in the main portion 1 and is arranged adjacent to the bottom surface 12, but the present disclosure is not limited thereto.

Moreover, the external connection portion 2 includes a first pad set 21, a second pad set 22 corresponding in position to the first pad set 21, a connection circuit 23, and a signal pad set 24 that is arranged between the first pad set 21 and the second pad set 22. In the present embodiment, the first pad set 21, the signal pad set 24, and the second pad set 22 are formed on the top surface 11 of the main portion 1 and are sequentially arranged along a layout direction D.

Furthermore, the first pad set 21 and the second pad set 22 are electrically coupled to each other through the connection circuit 23, and the connection circuit 23 in the present embodiment is arranged under the top surface 11 of the main portion 1 and is electrically coupled to the circuit assembly 13, but the present disclosure is not limited thereto. For example, in other embodiments of the present disclosure not shown in the drawings, the circuit assembly 13 can be arranged adjacent to the top surface 11, and the connection circuit 23 can be formed on the top surface 11.

Specifically, the first pad set 21 includes a plurality of first pads 211 arranged on the top surface 11, the second pad set 22 includes a plurality of second pads 221 arranged on the top surface 11 and respectively corresponding in position to the first pads 211, and the signal pad set 24 includes a plurality of signal pads 241 arranged on the top surface 11. Each of the first pads 211 and the corresponding second pad 221 are electrically coupled to each other through the connection circuit 23, and any one of the first pads 211 and the corresponding second pad 223 are jointly configured to transmit electricity or are jointly configured to be grounded.

In other words, any one of the first pads 211 and the corresponding second pad 223 in the present embodiment can be jointly referred to as a pad set P. Accordingly, the first pad set 21 and the second pad set 22 in the present embodiment can be jointly regarded as a plurality of the pad sets P. However, in other embodiments of the present disclosure not shown in the drawings, the top surface 11 of the chip 100 can have at least one pad set P and at least one signal pad 241.

Moreover, for the connection relationship of any one of the pad sets P, the connection circuit 23 includes a first segment 231 electrically coupled (through connection) to the first pad 211, a second segment 232 electrically coupled (through connection) to the second pad 221, and a common segment 233 that is (connected and) electrically coupled to the circuit assembly 13. In other words, the circuit assembly 13 can be electrically coupled to the first segment 231 and the second segment 232 through the common segment 233 of the connection circuit 23.

In addition, the first pads 211, the signal pads 241, and the second pads 221 are arranged sequentially in a predetermined order along the layout direction D that is defined toward a periphery of the chip 100. In the present embodiment, the top surface 11 of the chip 100 has a plurality of outer edges 111, and the second pad set 22 are arranged along one of the outer edges 111 that is defined as a layout edge 111a. Moreover, the layout direction D in the present embodiment can be a direction from a center of the top surface 11 of the chip 100 toward the layout edge 111a.

It should be noted that the layout direction D preferably refers to a direction in which the first pad set 21, the signal pad set 24, and the second pad set 22 are substantially arranged. However, any one of the pad sets P and the corresponding signal pad 241 adjacent thereto can be provided along the layout direction D in an aligned arrangement, a staggered arrangement, or an aligned arrangement mixed with a staggered arrangement.

In summary, the pad set P is operable by choosing one of the first pad 211 and the second pad 221. Specifically, one of the first pad 211 and the second pad 221 of the pad set P is configured to be connected to a wire, and another one of the first pad 211 and the second pad 221 of the pad set P is unconnected to any wire. Accordingly, when the circuit assembly 13 is electrically coupled to an object outside of the chip 100 through the pad set P, the pad set P is operable by choosing one of the first pad 211 and the second pad 221 (to electrically couple to the object in a wire-bonding manner).

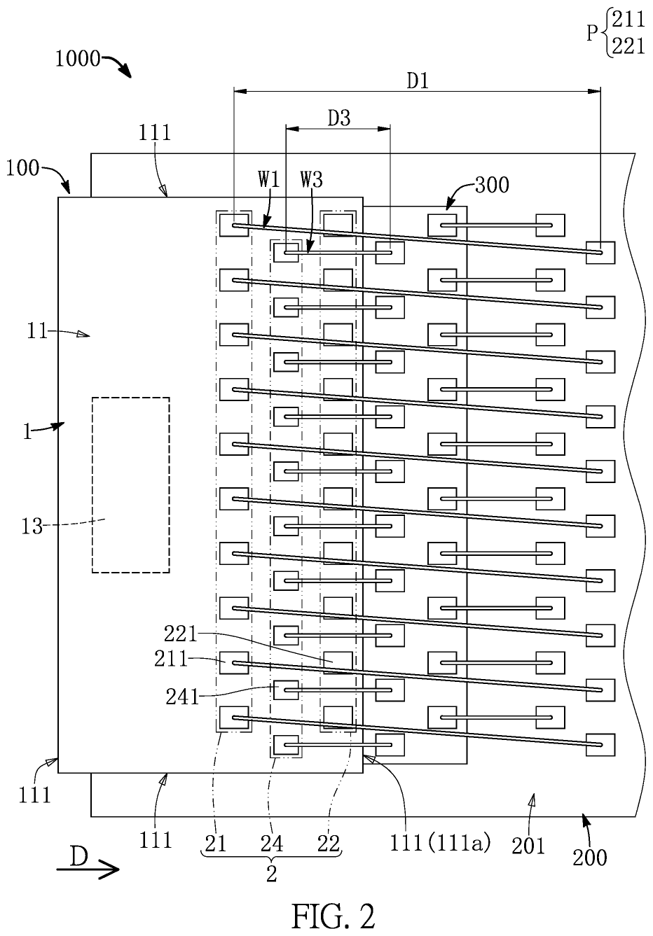

For example, as shown in FIG. 1 and FIG. 2, when the circuit assembly 13 is electrically coupled to the object outside of the chip 100 through the first pad 211, the second pad 221 is not electrically coupled to the object in a wire-bonding manner. Furthermore, when the first pad 211 and the signal pad 241 are configured for a wire-bonding process, the first pad 211 is capable of being connected to a first wire W1, and the signal pad 241 is capable of being connected to a signal wire W3 that is not longer than the first wire W1.

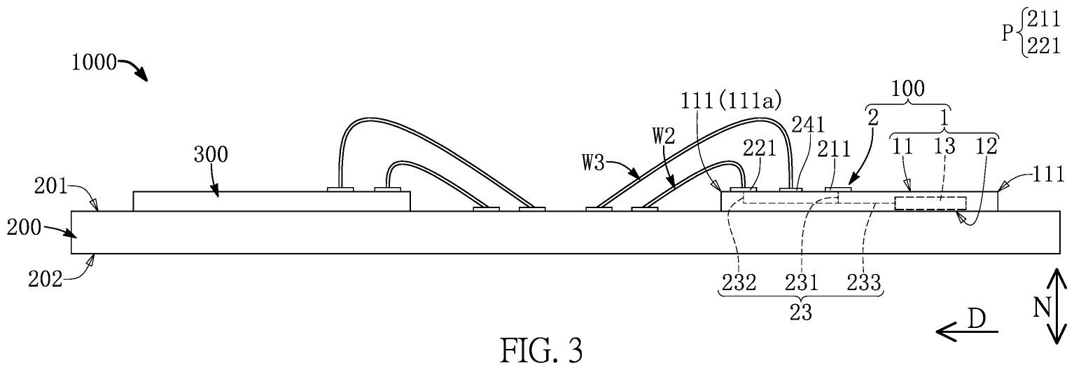

Or, as shown in FIG. 3 to FIG. 6, when the circuit assembly 13 is electrically coupled to the object outside of the chip 100 through the second pad 221, the first pad 211 is not electrically coupled to the object in a wire-bonding manner. Furthermore, when the second pad 221 and the signal pad 241 are configured for a wire-bonding process, the second pad 221 is capable of being connected to a second wire W2, and the signal pad 241 is capable of being connected to a signal wire W3 that is not shorter than the second wire W2.

The above description describes the structure of the chip 100 provided by the present embodiment, and the following description describes the connection relationship of the chip 100 and other components. The substrate 200 has an upper surface 201 and a lower surface 202 that is opposite to the upper surface 201, and the substrate 200 defines a normal direction N being perpendicular to the upper surface 201.

Moreover, the electronic component 300 is assembled onto the upper surface 201 of the substrate 200, and the electronic component 300 is electrically coupled to substrate 200 in a wire-bonding manner, but the present disclosure is not limited thereto. For example, in other embodiments of the present disclosure not shown in the drawings, the electronic component 300 is electrically coupled to substrate 200 in a flip-chip manner.

It should be noted that the chip 100 in the present embodiment is a main control chip, and the electronic component 300 is a DDR SDRAM (Double Data Rate Synchronous Dynamic Random Access Memory), but the present disclosure is not limited thereto. For example, in other embodiments of the present disclosure not shown in the drawings, any one of the chip 100 and the electronic component 300 can be adjusted or changed according to design requirements.

Moreover, according to different design requirements, the chip 100 in the present embodiment can be selectively operable in a stacking mode through the first pad set 21 or a side-by-side mode through the second pad set 22. The following description describes the above modes of the chip 100.

As shown in FIG. 1 and FIG. 2, when the chip 100 is operated in the stacking mode, the chip 100 is stacked onto the electronic component 300 (through the bottom surface 12), the signal pad set 24 of the chip 100 is electrically coupled to the electronic component 300 in a wire-bonding manner (e.g., each of the signal pads 241 is electrically coupled to the electronic component 300 through one of the signal wires W3), and the first pad set 21 of the chip 100 is electrically coupled to the substrate 200 in a wire-bonding manner (e.g., each of the first pads 211 is electrically coupled to the substrate 200 through one of the first wires W1).

Specifically, when the chip 100 is operated in the stacking mode, the first wires W1 are located above the signal wires W3, the first wires W1 do not cover any one of the signal wires W3 along the normal direction N, and each of the second pads 221 is not connected to any wire. Furthermore, a length D1 of the first wire W1 in the present embodiment is not less than a length D3 of the signal wire W3, but the present disclosure is not limited thereto.

As shown in FIG. 3 to FIG. 6, when the chip 100 is operated in the side-by-side mode, the chip 100 is disposed on the upper surface 201 of the substrate 200 (through the bottom surface 12) and is spaced apart from the electronic component 300, the signal pad set 24 of the chip 100 is electrically coupled to the electronic component 300, and the second pad set 22 of the chip 100 is electrically coupled to the substrate 200 in a wire-bonding manner (e.g., each of the second pads 221 is electrically coupled to the substrate 200 through one of the second wires W2).

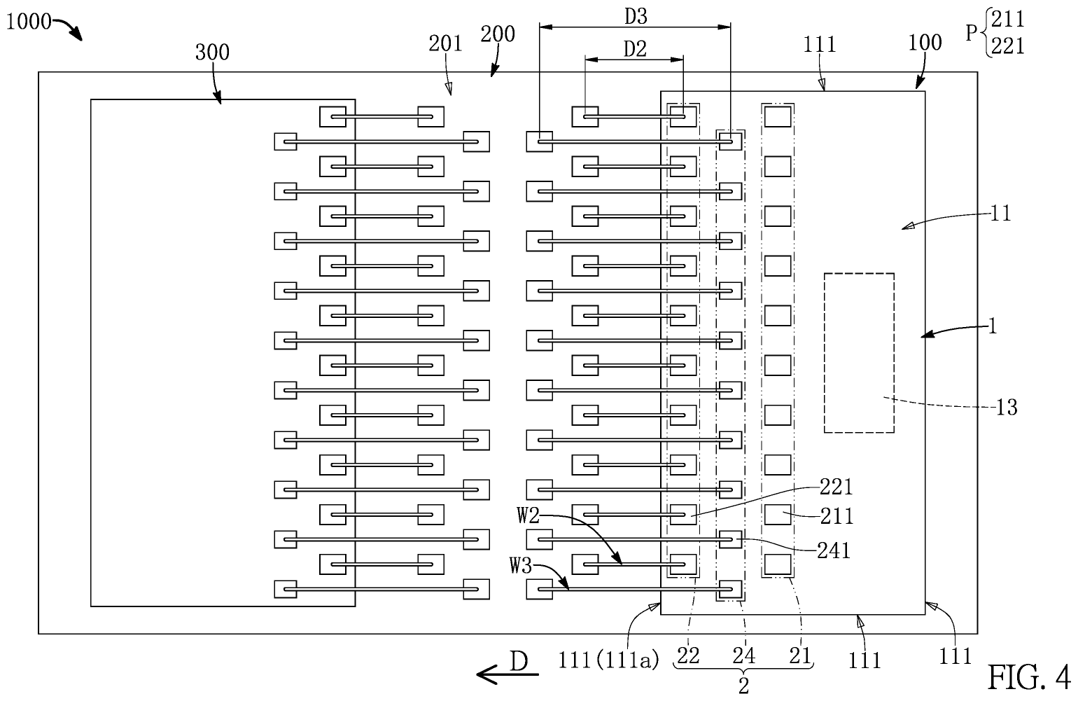

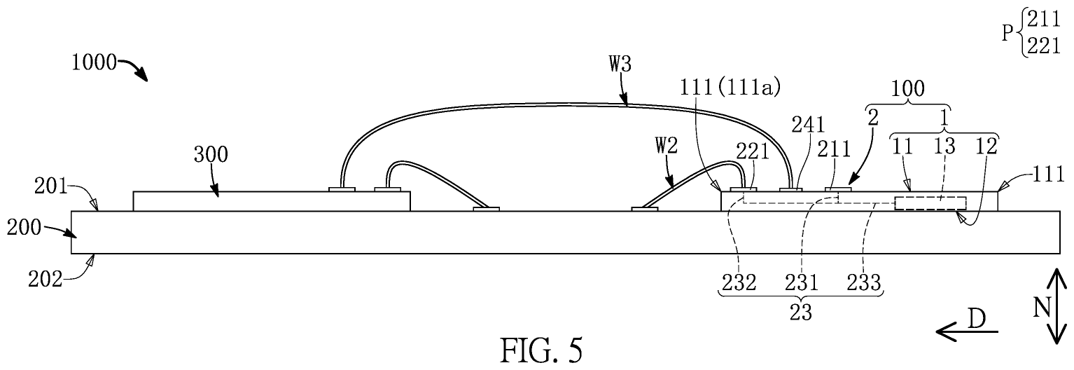

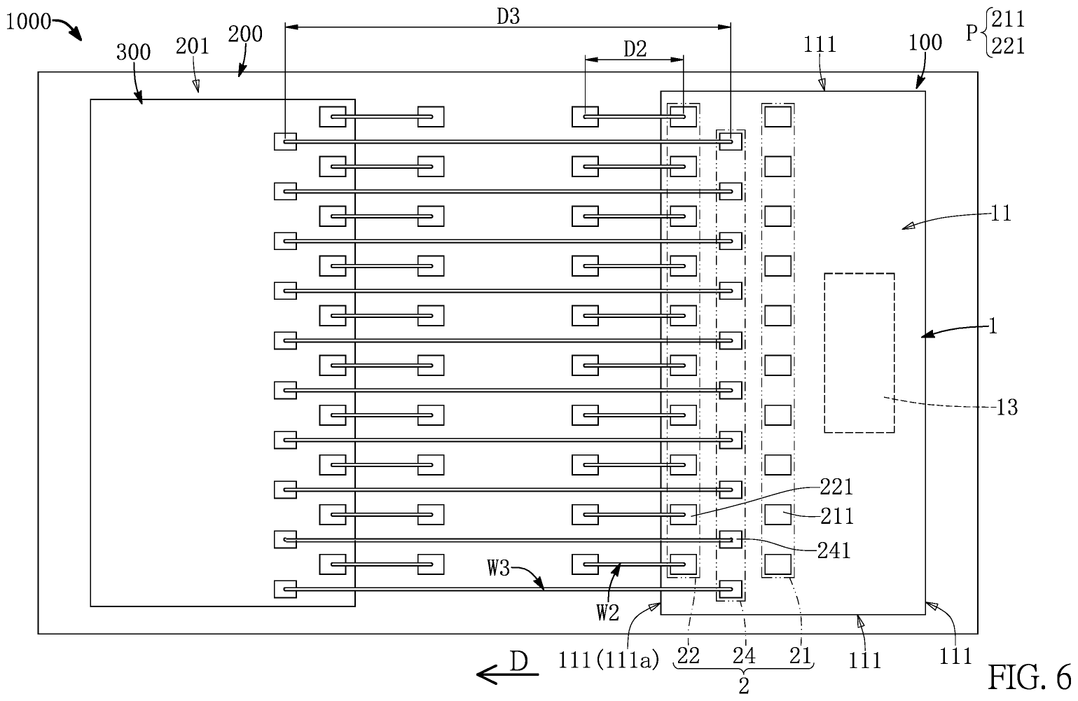

Specifically, when the chip 100 is operated in the side-by-side mode as shown in FIG. 3 and FIG. 4, the signal pad set 24 of the chip 100 is electrically coupled to the substrate 200 in a wire-bonding manner (e.g., each of the signal pads 241 is electrically coupled to the substrate 200 through one of the signal wires W3), and the chip 100 and the electronic component 300 are electrically coupled to each other through the substrate 200. Or, when the chip 100 is operated in the side-by-side mode as shown in FIG. 5 and FIG. 6, the signal pad set 24 of the chip 100 is electrically coupled to the electronic component 300 in a wire-bonding manner (e.g., each of the signal pads 241 is electrically coupled to the electronic component 300 through one of the signal wires W3).

Moreover, as shown in FIG. 3 to FIG. 6, when the chip 100 is operated in the side-by-side mode, the second wires W2 are located under the signal wires W3, the signal wires W3 do not cover any one of the second wires W2 along the normal direction D, and each of the first pads 211 is not connected to any wire. Furthermore, a length D2 of the second wire W2 in the present embodiment is not greater than the length D3 of the signal wire W3, but the present disclosure is not limited thereto.

In summary, in any one of the integrated circuit structure 1000 and the chip 100 provided by the present embodiment, the first pad set 21 (e.g., the first pad 211) and the second pad set 22 (e.g., the second pad 221) are cooperated with the connection circuit 23 for being electrically coupled to each other, so that the chip 100 can have a high flexibility in use. For example, the chip 100 can be operated by choosing one of the first pad set 21 (e.g., the first pad 211) and the second pad set 22 (e.g., the second pad 221), thereby enabling the chip 100 to be assembled in the stacking mode or in the side-by-side mode according to different requirements.

### Second Embodiment

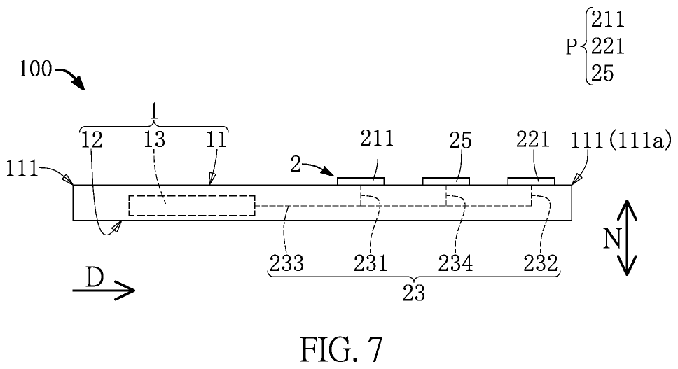

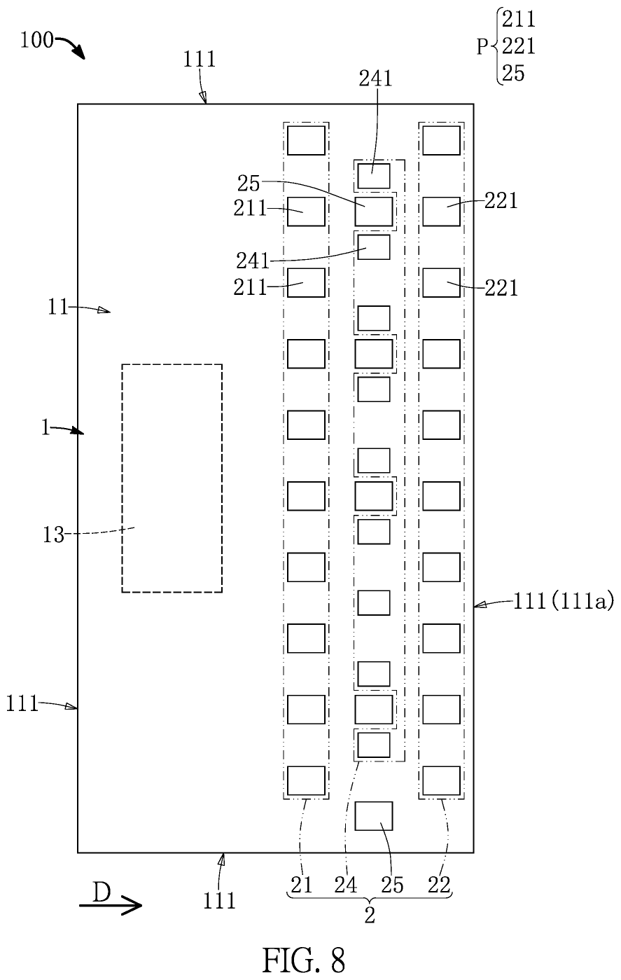

Referring to FIG. 7 and FIG. 8, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the top surface 11 of the chip 100 further includes at least one third pad 25 that is arranged between the first pad set 21 and the second pad set 22 and that is preferably arranged in one row with the signal pads 241, but the present disclosure is not limited thereto.

Moreover, the at least one third pad 25 is electrically coupled to at least one of the first pads 211 and the corresponding second pad 221 through the connection circuit 23. In other words, the pad set P can further include one of the third pads 25, and the connection circuit 23 further includes a third segment 234 (connected and) electrically coupled to the third pads 25, so that the circuit assembly 13 is electrically coupled to the first segment 231, the second segment 232, and the third segment 234 through the common segment 233 of the connection circuit 23.

### Third Embodiment

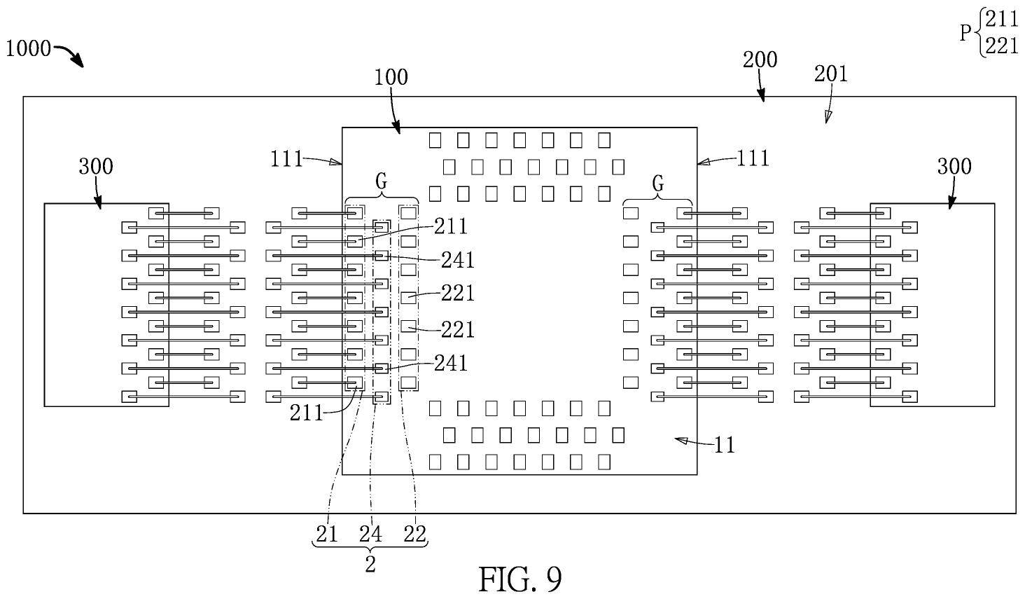

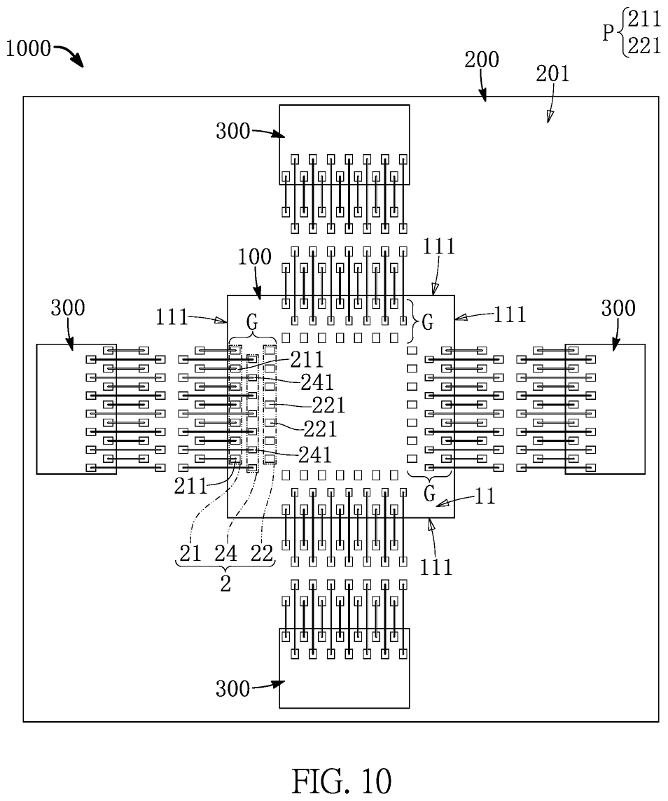

Referring to FIG. 9 and FIG. 10, a third embodiment of the present disclosure, which is similar to the first embodiment of the present disclosure, is provided. For the sake of brevity, descriptions of the same components in the first and third embodiments of the present disclosure will be omitted herein, and the following description only discloses different features between the first and third embodiments.

In the present embodiment, the first pads 211 are arranged in a first annular arrangement, the signal pads 241 are arranged in a second annular arrangement, and the second pads 221 are arranged in a third annular arrangement. Moreover, the first pad set 21, the signal pad set 24, and the second pad set 22 are sequentially arranged from an interior of the top surface 11 toward an exterior of the top surface 11.

Specifically, the top surface 11 of the chip 100 includes a plurality of outer edges 111. Moreover, at least one of the first pads 211, at least one of the signal pads 241, and at least one of the second pads 221 are arranged adjacent to one of the outer edges 111 and are jointly defined as an operation unit G. In other words, a quantity of the operation unit G of the chip 100 is more than one and is equal to a quantity of the outer edges 111.

Moreover, each of the outer edges 111 of the chip 100 can correspond in position to one of the operation units G, and the chip 100 is electrically coupled to any one of the electronic component 300 through the signal pads 241 of one of the operation units G. The connection relationship between each of the operation units G and the corresponding electronic component 300 in the present embodiment is similar to that of the first embodiment, and will be omitted herein for the sake of brevity.

### Beneficial Effects of the Embodiments

In conclusion, in any one of the integrated circuit structure and the chip provided by the present disclosure, the first pad set (e.g., the first pad) and the second pad set (e.g., the second pad) are cooperated with the connection circuit for being electrically coupled to each other, so that the chip can have a high flexibility in use. For example, the chip can be operated by choosing one of the first pad set (e.g., the first pad) and the second pad set (e.g., the second pad), thereby enabling the chip to be assembled in the stacking mode or in the side-by-side mode according to different requirements.

Moreover, in the integrated circuit structure provided by the present disclosure, the first pad set, the signal pad set, and the second pad set are cooperatively arranged with each other in a specific layout, so that the wires connected to the first pads and the signal pads in the wire-bonding process can be staggered with each other, and the wires connected to the second pads and the signal pads in the wire-bonding process can be staggered with each other, thereby facilitating the assembling of the chip.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An integrated circuit structure, comprising:
a substrate having an upper surface and a lower surface opposite to the first surface;
an electronic component disposed on the upper surface, wherein the electronic component is electrically coupled to the substrate in a wire-bonding manner; and
a chip comprising a connection circuit, a first pad set, a signal pad set, and a second pad set, wherein the first pad set, the signal pad set, and the second pad set are sequentially arranged on a top surface of the chip along a layout direction, and wherein the first pad set and the second pad set are electrically coupled to each other through the connection circuit, so that the chip is selectively operable in a stacking mode through the first pad set or a side-by-side mode through the second pad set;
wherein, when the chip is operated in the stacking mode, the chip is stacked onto the electronic component, the signal pad set is electrically coupled to the electronic component in a wire-bonding manner, and the first pad set is electrically coupled to the substrate in a wire-bonding manner;
wherein, when the chip is operated in the side-by-side mode, the chip is disposed on the upper surface of the substrate, the signal pad set is electrically coupled to the electronic component, and the second pad set is electrically coupled to the substrate in a wire-bonding manner.

2. The integrated circuit structure according to claim 1, wherein the first pad set comprises a plurality of first pads, the signal pad set comprises a plurality of signal pads, and the second pad set comprises a plurality of second pads respectively corresponding in position to the first pads, and wherein each of the first pads and the corresponding second pad are electrically coupled to each other through the connection circuit so as to be operable by choosing one therefrom.

3. The integrated circuit structure according to claim 2, wherein any one of the first pads and the corresponding second pad are jointly configured to transmit electricity or are jointly configured to be grounded.

4. The integrated circuit structure according to claim 2, wherein each of the signal pads is electrically coupled to the electronic component through one of a plurality of signal wires, wherein, when the chip is operated in the stacking mode, each of the first pads is electrically coupled to the substrate through one of a plurality of first wires, and the first wires are located above the signal wires, and wherein, when the chip is operated in the side-by-side mode, each of the second pads is electrically coupled to the substrate through one of a plurality of second wires, and the second wires are located under the signal wires.

5. The integrated circuit structure according to claim 4, wherein the substrate defines a normal direction perpendicular to the upper surface, and wherein, when the chip is operated in the stacking mode, any one of the signal wires is not covered by the first wires along the normal direction.

6. The integrated circuit structure according to claim 4, wherein the substrate defines a normal direction perpendicular to the upper surface, and wherein, when the chip is operated in the side-by-side mode, any one of the second wires is not covered by the signal wires along the normal direction.

7. The integrated circuit structure according to claim 4, wherein, when the chip is operated in the stacking mode, each of the second pads is not connected to any wire, and wherein, when the chip is operated in the side-by-side mode, each of the first pads is not connected to any wire.

8. The integrated circuit structure according to claim 2, wherein the first pads are arranged in a first annular arrangement, the signal pads are arranged in a second annular arrangement, and the second pads of the second pad set are arranged in a third annular arrangement, and wherein the first pad set, the signal pad set, and the second pad set are sequentially arranged from an interior of the top surface toward an exterior of the top surface.

9. The integrated circuit structure according to claim 8, wherein the top surface of the chip comprises a plurality of outer edges, wherein at least one of the first pads, at least one of the signal pads, and at least one of the second pads are arranged adjacent to one of the outer edges and are jointly defined as an operation unit, and wherein the chip is electrically coupled to the electronic component through the signal pads of the operation unit.

10. The integrated circuit structure according to claim 2, wherein the top surface of the chip includes at least one third pad arranged between the first pad set and the second pad set, and wherein the at least one third pad is electrically coupled to at least one of the first pads and the corresponding second pad.

11. The integrated circuit structure according to claim 1, wherein, when the chip is operated in the side-by-side mode, the signal pad set of the chip is electrically coupled to the substrate in a wire-bonding manner, and the chip and the electronic component are electrically coupled to each other through the substrate.

12. The integrated circuit structure according to claim 1, wherein, when the chip is operated in the side-by-side mode, the signal pad set of the chip is electrically coupled to the electronic component in a wire-bonding manner.

13. A chip, comprising:
a first pad set including a plurality of first pads;
a second pad set including a plurality of second pads respectively corresponding in position to the first pads;
a connection circuit, wherein each of the first pads and the corresponding second pad are electrically coupled to each other through the connection circuit so as to be operable by choosing one therefrom; and
a signal pad set arranged between the first pad set and the second pad set and including a plurality of signal pads.

14. The chip according to claim 13, wherein any one of the first pads and the corresponding second pad are jointly configured to transmit electricity or are jointly configured to be grounded.

15. The chip according to claim 13, wherein, in any one of the first pads and the corresponding second pad, one is configured to be connected to a wire, and another one is configured to be unconnected to any wire.

16. The chip according to claim 13, wherein the first pads of the first pad set are in an annular arrangement, the signal pads of the signal pad set are in an annular arrangement, and the second pads of the second pad set are in an annular arrangement, and wherein the first pad set, the signal pad set, and the second pad set are sequentially arranged from an interior of the top surface toward an exterior of the top surface.

17. The chip according to claim 13, wherein the top surface of the chip has a plurality of outer edges, wherein a part of the first pads, a part of the signal pads, and a part of the second pads are arranged adjacent to one of the outer edges and are jointly defined as an operation unit, and wherein the chip is configured to be electrically coupled to an electronic component through the signal pads of the operation unit.

18. A chip, comprising:
a main portion including a top surface and a circuit assembly that is arranged under the top surface;
a pad set including a first pad and a second pad both are arranged on the top surface;
a signal pad arranged on the top surface of the main portion and electrically coupled to the circuit assembly, wherein the first pad, the signal pad, and the second pad are arranged sequentially in a predetermined order along a layout direction defined toward a periphery of the chip; and
a connection circuit arranged under the top surface, wherein the connection circuit includes a first segment electrically coupled to the first pad, a second segment electrically coupled to the second pad, and a common segment that is electrically coupled to the circuit assembly;
wherein, when the circuit assembly is electrically coupled to an object outside of the chip through the pad set, the pad set is operable by choosing one of the first pad and the second pad to be electrically coupled to the object in a wire-bonding manner.

19. The chip according to claim 18, wherein, when the first pad and the signal pad are configured for a wire-bonding process, the first pad is capable of being connected to a first wire, and the signal pad is capable of being connected to a signal wire that is not longer than the first wire.

20. The chip according to claim 18, wherein, when the second pad and the signal pad are configured for a wire-bonding process, the second pad is capable of being connected to a second wire, and the signal pad is capable of being connected to a signal wire that is not shorter than the second wire.
